(19) United States
(12) Patent Application Publication
(10) Pub. No.: US 2025/0148172 A1
(43) Pub. Date: May 8, 2025

(54) INFORMATION PROCESSING SYSTEM, INFORMATION PROCESSING METHOD, AND INFORMATION PROCESSING PROGRAM

(71) Applicant: Resonac Corporation, Minato-ku, Tokyo (JP)

(72) Inventor: Ryosuke ARAI, Minato-ku, Tokyo (JP)

(21) Appl. No.: 18/838,065

(22) PCT Filed: Feb. 15, 2023
(86) PCT No.: PCT/JP2023/005319

§ 371 Date: Aug. 13, 2024

(30) Foreign Application Priority Data
Feb. 18, 2022 (JP) 2022-023558

(51) Int. Cl. G06F 30/27

(52) U.S. Cl. CPC G06F 30/27

(57) ABSTRACT

An information processing system according to an example includes at least one processor. The at least one processor is configured to: repeat optimization using a regression model, which calculates a physical property value of a composition from a feature vector indicating feature quantities of a candidate component group based on a plurality of candidate components, while performing exclusion processing for excluding at least one candidate component from the candidate component group; and identify feature quantities of one or more candidate components remaining after the repetition. The exclusion processing includes: selecting the feature vector corresponding to a solution for the physical property value obtained by the optimization; and excluding the at least one candidate component from the candidate component group based on the selected feature vector.

### TECHNICAL FIELD

One aspect of the present disclosure relates to an information processing system, an information processing method, and an information processing program.

### BACKGROUND ART

Conventionally, there have been known methods for searching for feature quantities of candidate components for forming a desired composition. For example, Patent Literature 1 describes a method for creating a blending plan for mixing a plurality of types of raw materials to be blended using mathematical programming. In Patent Literature 2, a method is known that plans a blending ratio of raw materials by solving a raw material blending plan formulated as a mixed integer programming problem including nonlinear variables.

### CITATION LIST

### Patent Literature

Patent Literature 1: Japanese Unexamined Patent Publication No. 2009-175804

Patent Literature 2: Japanese Unexamined Patent Publication No. 2020-149607

### SUMMARY OF INVENTION

### Technical Problem

In the methods described in Patent Literatures 1 and 2, if the number of types of candidate components is enormous, a significant amount of calculation time is required to obtain the feature quantities of candidate components for forming a desired composition. Therefore, a method for searching for such feature quantities at higher speed is desired.

### Solution to Problem

An information processing system according to an aspect of the present disclosure includes at least one processor. The at least one processor is configured to: repeat optimization using a regression model, which calculates a physical property value of a composition from a feature vector indicating feature quantities of a candidate component group based on a plurality of candidate components, while performing exclusion processing for excluding at least one candidate component from the candidate component group; and identify feature quantities of one or more candidate components remaining after the repetition. The exclusion processing includes: selecting the feature vector corresponding to a solution for the physical property value obtained by the optimization; and excluding the at least one candidate component from the candidate component group based on the selected feature vector.

An information processing method according to one aspect of the present disclosure is executed by an information processing system including at least one processor. The information processing method includes: repeating optimization using a regression model, which calculates a physical property value of a composition from a feature vector indicating feature quantities of a candidate component group based on a plurality of candidate components, while performing exclusion processing for excluding at least one candidate component from the candidate component group; and identifying feature quantities of one or more candidate components remaining after the repeating. The exclusion processing includes: selecting the feature vector corresponding to a solution for the physical property value obtained by the optimization; and excluding the at least one candidate component from the candidate component group based on the selected feature vector.

An information processing program according to one aspect of the present disclosure causes a computer to execute: repeating optimization using a regression model, which calculates a physical property value of a composition from a feature vector indicating feature quantities of a candidate component group based on a plurality of candidate components, while performing exclusion processing for excluding at least one candidate component from the candidate component group; and identifying feature quantities of one or more candidate components remaining after the repeating. The exclusion processing includes: selecting the feature vector corresponding to a solution for the physical property value obtained by the optimization; and excluding the at least one candidate component from the candidate component group based on the selected feature vector.

In such aspects, the optimization using the regression model that calculates the physical property value of the composition from the feature vector of the candidate component group is repeatedly performed while reducing the number of types of candidate components. By performing the optimization in stages while narrowing down the candidate components, it is possible to search for the feature quantities of candidate components for forming the desired composition at high speed.

### Advantageous Effects of Invention

According to one aspect of the present discloser, it is possible to

search for the feature quantities of candidate components for forming a desired composition at higher speed.

### BRIEF DESCRIPTION OF DRAWINGS

FIG. 1 is a diagram showing an example of the functional configuration of an information processing system according to an embodiment.

FIG. 2 is a flowchart showing an example of the operation of the information processing system according to the embodiment.

FIG. 3 is a flowchart showing an example of optimization.

### DESCRIPTION OF EMBODIMENTS

Hereinafter, an embodiment of the present disclosure will be described in detail with reference to the accompanying diagrams. In the description of the diagrams, the same or equivalent elements are denoted by the same reference numerals, and the repeated description thereof will be omitted.

### System Configuration

An information processing system 10 according to an embodiment is a computer system that searches for feature quantities of candidate components for forming a desired composition. The composition refers to a substance that is formed by processing one or more components. Typically, the composition is obtained using two or more components. For example, the composition may be an inorganic composition, an organic composition such as a resin composition, or a feed composition. The component of the composition refers to a substance that are intentionally used to form the composition. The component may or may not remain in the original form when the composition is completed. In the present disclosure, a component that may form the desired composition is also referred to as a “candidate component”. Individual candidate components are prepared corresponding to the composition, and may be, for example, various materials such as inorganic materials and organic materials.

In one example, the information processing system 10 repeatedly performs optimization using a pre-trained regression model to finally identify feature quantities of two or more candidate components for forming the desired composition. In the present disclosure, the “desired composition” refers to a composition having a desired physical property value. An example of the feature quantity of the candidate component is a blending amount. The blending amount may be expressed as an absolute amount, may be expressed as a ratio (blending ratio), or may be expressed as another indicator. Each feature quantity may be expressed as a weighted average or a linear weighted sum. For example, the blending amount may be expressed as the weighted average. Examples of physical property values of the composition include glass transition temperature, elastic modulus, and coefficient of expansion.

The regression model is a calculation model for calculating values of one or more objective variables y based on values of one or more explanatory variables x. In one example, the regression model receives, as explanatory variables, a feature vector based on the feature quantities of candidate component group based on a plurality of candidate components, and calculates, as an objective variable, a physical property value of the composition. In the present disclosure, it should be noted that the term “a plurality of candidate components” means a plurality of types of candidate components. The candidate component group may also be said to be a set of the plurality of candidate components. The feature vector refers to an n-dimensional vector that indicates the feature quantity of each of n candidate components as vector elements, and may be expressed as a one-dimensional array.

In one optimization, the information processing system 10 inputs each feature vector to the regression model to obtain the physical property values of the composition, while changing at least part of the feature vector. The information processing system 10 selects a tentative solution from a plurality of physical property values, and selects a feature vector corresponding to that solution, that is, a feature vector that has input to the regression model to obtain that solution. The information processing system 10 performs exclusion processing for excluding at least one candidate component from the candidate component group based on the selected feature vector. Then, the information processing system 10 performs the optimization again on the assumption that some of the candidate components has been excluded. The information processing system 10 repeats the optimization while performing the exclusion processing, and outputs the feature quantity of each of one or more candidate components remaining after the repetition, as a final processing result.

In this manner, the information processing system 10 performs the optimization in stages while narrowing down the candidate components. As the number of candidate components that are considered in an optimization problem gradually decreases, the time required for each optimization decreases with each repetition of the optimization. Therefore, the time required to obtain the final processing result may be reduced compared with optimization that considers all candidate components from start to finish. Such an increase in processing speed may be noticeable in a case where there are an extremely large number of candidate components, such as in material development.

The information processing system 10 consists of one or more computers. In a case where a plurality of computers are used, one information processing system 10 is logically constructed by connecting these computers to each other through a communication network, such as the Internet or an intranet.

Each computer forming the information processing system 10 generally includes a processor, a memory, and a communication interface as hardware devices. The processor is, for example, a CPU, and the memory is a flash memory, a hard disk, and the like. However, types of the hardware devices forming the information processing system 10 are not limited to those and may be selected arbitrarily. Each function of the information processing system 10 is realized by the processor executing a program stored in the memory.

An information processing program causing a computer to function as the information processing system 10 includes a program code for implementing each functional module of the information processing system 10. The information processing program may be provided after being non-temporarily recorded on a tangible recording medium, such as a CD-ROM, a DVD-ROM, or a semiconductor memory. Alternatively, the information processing program may be provided through a communications network as a data signal superimposed on a carrier wave. The provided information processing program is stored in the memory, for example.

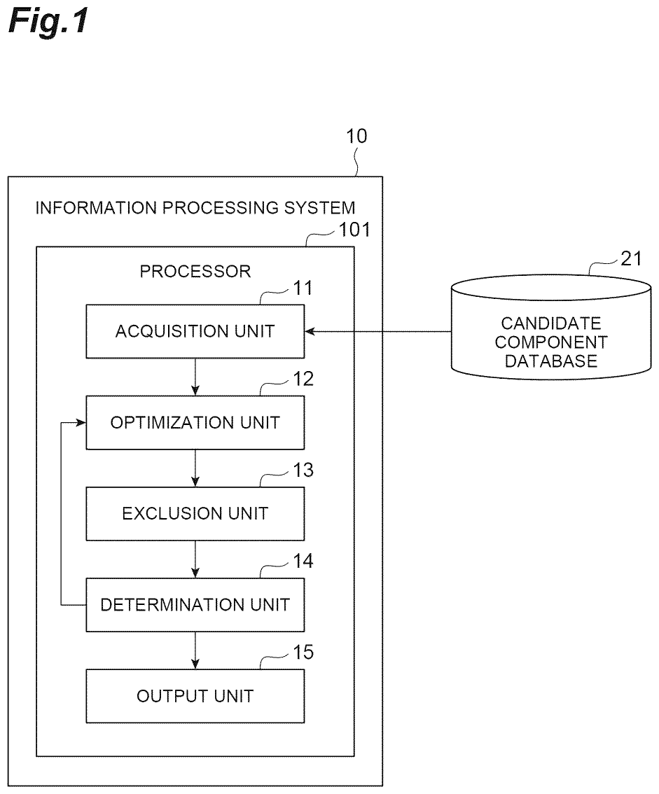

FIG. 1 is a diagram showing an example of the functional configuration of the information processing system 10. In this example, the information processing system 10 includes a processor 101. In one example, the processor 101 functions as an acquisition unit 11, an optimization unit 12, an exclusion unit 13, a determination unit 14, and an output unit 15. The acquisition unit 11 is a functional module that acquires a reference physical property value, which is the desired physical property value, and the candidate component group. The optimization unit 12 is a functional module that performs the optimization using the regression model. The exclusion unit 13 is a functional module that excludes at least one candidate component from the candidate component group. The determination unit 14 is a functional module that determines whether or not to terminate the repetition of the optimization. The output unit 15 is a functional module that outputs a processing result. In one example, the information processing system 10 accesses a

candidate component database 21 through a given communications network. The communication network may include at least one of the Internet and an intranet. The communication network may be configured using at least one of a wired network and a wireless network. The candidate component database 21 may be a component of the information processing system 10, or may be provided in a computer system separate from the information processing system 10.

The candidate component database 21 is a database that stores candidate component data indicating individual candidate components. In one example, the candidate component data indicates a plurality of available components.

### Operation of System

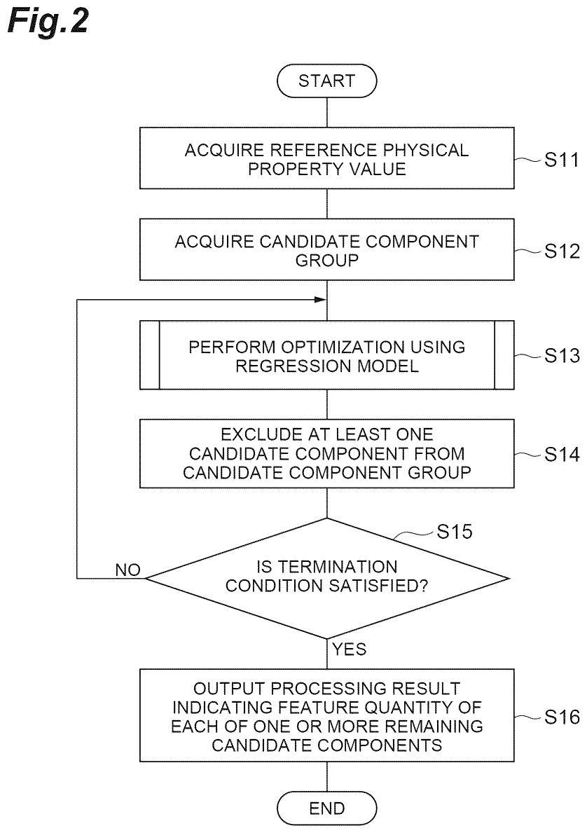

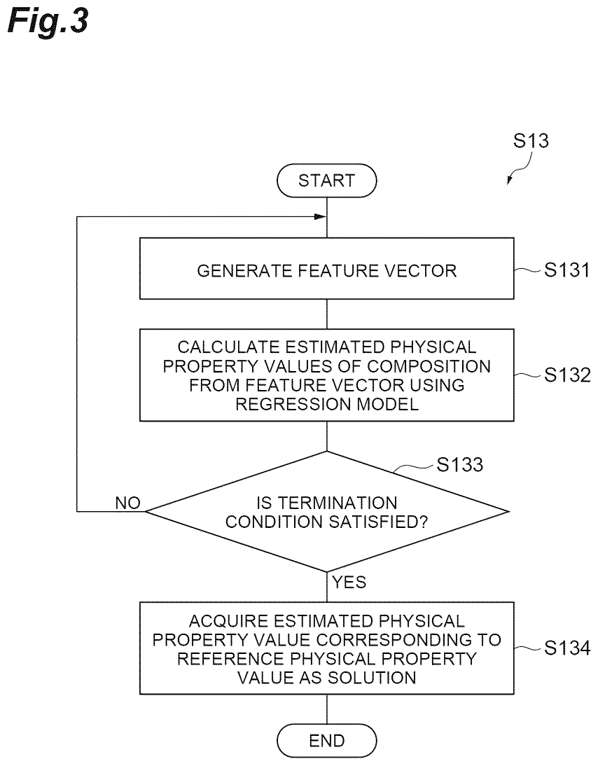

The operation of the information processing system 10 and an information processing method according to the present embodiment will be described with reference to FIGS. 2 and 3. FIG. 2 is a flowchart showing an example of processing in the information processing system 10. FIG. 3 is a flowchart showing an example of the optimization processing.

In step S11, the acquisition unit 11 acquires the reference physical property value. In one example, the acquisition unit 11 receives the reference physical property value input by a user. Alternatively, the acquisition unit 11 may read the reference physical property value from a physical property value database prepared in advance, or may receive the reference physical property value transmitted from another computer.

In step S12, the acquisition unit 11 acquires the candidate component group. In one example, the acquisition unit 11 accesses the candidate component database 21 to read the candidate component data indicating the plurality of candidate components and acquire the plurality of candidate components as the candidate component group. The acquisition unit 11 may acquire all candidate components recorded in the candidate component database 21 as the candidate component group, or may acquire at least two candidate components of these candidate components as the candidate component group. Alternatively, the acquisition unit 11 may receive the plurality of candidate components input by the user as the candidate component group without accessing the candidate component database 21. Alternatively, the acquisition unit 11 may receive the candidate component group transmitted from another computer.

In step S13, the optimization unit 12 performs optimization of the feature quantities of the candidate components using the regression model. The “optimization of the feature quantities of candidate components” refers to a method of searching for one or more candidate components and a feature quantity of each candidate component in order to obtain a composition having a physical property value that matches or is similar to the reference physical property value.

An example of the optimization processing will be described with reference to FIG. 3. In step S131, the optimization unit 12 generates the feature vector. In one example, the optimization unit 12 generates the feature vector indicating the feature quantities of the candidate component group. The number of dimensions of the feature vector corresponds to the number of types of the candidate components. That is, in a case where the number of types of the candidate components is n, the generated feature vector is an n-dimensional vector indicating n feature quantities as vector elements. The optimization unit 12 sets the feature quantity of each candidate component by using, for example, random search.

In step S132, the optimization unit 12 calculates the physical property value of the composition from the feature vector using the regression model. In the present disclosure, the physical property value calculated by the regression model is also referred to as “estimated physical property value”. The optimization unit 12 calculates the estimated physical property values by inputting the feature vector to the regression model. The regression model used by the optimization unit 12 may be Support Vector Regression (SVR) or Gaussian Process Regression (GPR). The optimization unit 12 may use the regression model stored in a given memory, or may access the regression model that exists outside the information processing system 10 through a given communication network.

In step S133, the optimization unit 12 determines whether or not a termination condition of the calculation of the estimated physical property value is satisfied. For example, the termination condition may be set based on the number of executions of the regression model. The number of executions may be set by the user or may be determined in advance.

In a case where the termination condition is not satisfied (NO in step S133), the process returns to step S131, in which the optimization unit 12 generates a new feature vector. The optimization unit 12 changes at least one vector element of the feature vector to generate the new feature vector. In order to generate the new feature vector, the optimization unit 12 may use the random search, a combination of the random search and the gradient method, or a combination of the random search and the Newton's method. Alternatively, the optimization unit 12 may generate the new feature vector using an acquisition function of Bayesian optimization.

In a case where the termination condition is satisfied (YES in step S133), the process proceeds to step S134, in which the optimization unit 12 acquires at least one estimated physical property value corresponding to the reference physical property value, among the plurality of estimated physical property values, as a solution. The “estimated physical property value corresponding to the reference physical property value” may be, for example, an estimated physical property value that matches the reference physical property value or an estimated physical property value that most closely approximates the reference physical property value.

FIG. 2 is referred to again. In step S14, the exclusion unit 13 excludes at least one candidate component from the candidate component group. That is, step S14 is the exclusion processing. The exclusion unit 13 selects a feature vector corresponding to the estimated physical property value acquired as the solution in step S13. Then, the exclusion unit 13 applies at least one exclusion requirement to each feature quantity indicated by the feature vector to exclude at least one candidate component satisfying any exclusion requirement from the candidate component group. For example, the exclusion unit 13 may exclude a candidate component satisfying the exclusion requirement the feature quantity is equal to or less than a given threshold value. Hereinafter, this exclusion requirement is also referred to as the “first exclusion requirement”. Alternatively, the exclusion unit 13 may exclude a candidate component having the minimum feature quantity in the feature vector. Hereinafter, this exclusion requirement is also referred to as the “second exclusion requirement”. Alternatively, the exclusion unit 13 may perform processing for excluding at least one candidate component using the first exclusion requirement, and if no candidate component is excluded by that processing, the exclusion unit 13 may exclude at least one candidate component using the second exclusion requirement. Alternatively, the exclusion unit 13 may exclude a candidate component having the maximum feature quantity in the feature vector. In one example, the exclusion unit 13 fixes the feature quantity of a candidate component to be excluded to zero in the feature vector, thereby excluding that candidate component from the candidate component group.

In step S15, the determination unit 14 determines whether or not the termination condition of the repetition of the optimization is satisfied. For example, the termination condition may be set based on the number of types of candidate components remaining in the candidate component group, that is, the number of candidate components whose feature quantities are not fixed to zero in the feature vector. In this case, if the number is equal to or less than a given threshold value, the determination unit 14 determines that the termination condition is satisfied. Alternatively, the termination condition may be that the optimization processing and the exclusion processing have been performed a given number of times.

In a case where the termination condition is not satisfied (NO in step S15), the process returns to step S13. In step S13, the optimization unit 12 performs the optimization processing again, and in step S14, the exclusion unit 13 executes the exclusion processing again.

In step S13 that is repeated, at least some of the feature quantities of the feature vector are fixed to zero. In step S131, the optimization unit 12 generates the new feature vector by setting the feature quantity of each of a plurality of remaining candidate components using various methods, such as the random search, the gradient method, the Newton's method, and an acquisition function, while fixing the feature quantities of the excluded candidate components to zero. In this case, the number of dimensions of the generated feature vector is substantially a number obtained by subtracting the number of excluded candidate components from initial number of dimensions of the feature vector. For example, in a case where the initial feature vector is n-dimensional and three candidate components are excluded, a newly generated feature vector is substantially (n−3)-dimensional. Therefore, the number of dimensions of the newly generated feature vector substantially decreases with each repetition of the optimization processing and the exclusion processing.

In a case where the termination condition is satisfied (YES in step S15), the process proceeds to step S16, in which the output unit 15 outputs the processing result. For example, the output unit 15 outputs the feature quantity of each of the one or more remaining candidate components as the processing result. Alternatively, the output unit 15 may output the estimated physical property values together with that feature quantities as the processing result. For example, the output unit 15 may store the processing result in a given database, may transmit the processing result to another computer or computer system, or may display the processing result on a display device. Alternatively, the output unit 15 may output the processing result to another functional module for subsequent processing in the information processing system 10.

As described above, the information processing system 10 repeats the optimization using the regression model, which calculates the physical property value of the composition from the feature vector indicating the feature quantities of the candidate component group based on the plurality of candidate components, while performing the exclusion processing for excluding at least one candidate component from the candidate component group, until the termination condition is satisfied in step S15. In a case of searching for p or less candidate components forming the desired composition from a candidate component group that is a set of n candidate components (where p<n), the information processing system 10 obtains a tentative solution in consideration of all of the n candidate components in first optimization. This may be said to be a process of calculating a relaxed problem with relaxed constraints on the feature vector to search for a relaxed solution. The fact that some candidate components are excluded by the exclusion processing and the corresponding feature quantities are fixed to zero means that constraints are added. In other words, repeating the optimization while performing the exclusion processing may be said to be a process of searching for an optimal solution while gradually increasing the number of constraints.

### Effects

As described above, the information processing system according to one aspect of the present disclosure includes at least one processor. The at least one processor is configured to: repeat optimization using a regression model, which calculates a physical property value of a composition from a feature vector indicating feature quantities of a candidate component group based on a plurality of candidate components, while performing exclusion processing for excluding at least one candidate component from the candidate component group; and identify feature quantities of one or more candidate components remaining after the repetition. The exclusion processing includes: selecting the feature vector corresponding to a solution for the physical property value obtained by the optimization; and excluding the at least one candidate component from the candidate component group based on the selected feature vector.

An information processing method according to one aspect of the present disclosure is executed by the information processing system including at least one processor. The information processing method includes: repeating optimization using a regression model, which calculates a physical property value of a composition from a feature vector indicating feature quantities of a candidate component group based on a plurality of candidate components, while performing exclusion processing for excluding at least one candidate component from the candidate component group; and identifying feature quantities of one or more candidate components remaining after the repeating. The exclusion processing includes: selecting the feature vector corresponding to a solution for the physical property value obtained by the optimization; and excluding the at least one candidate component from the candidate component group based on the selected feature vector.

An information processing program according to one aspect of the present disclosure causes a computer to execute: repeating optimization using a regression model, which calculates a physical property value of a composition from a feature vector indicating feature quantities of a candidate component group based on a plurality of candidate components, while performing exclusion processing for excluding at least one candidate component from the candidate component group; and identifying feature quantities of one or more candidate components remaining after the repeating. The exclusion processing includes: selecting the feature vector corresponding to a solution for the physical property value obtained by the optimization; and excluding the at least one candidate component from the candidate component group based on the selected feature vector.

In such aspects, the optimization using the regression model that calculates the physical property value of the composition from the feature vector of the candidate component group is repeatedly performed while reducing the number of types of candidate components. By performing the optimization in stages while narrowing down the candidate components, it is possible to search for the feature quantities of candidate components for forming a desired composition at high speed. For example, compared with metaheuristic methods such as Ant Colony Optimization (ACO) and conventional methods such as random search, the information processing system according to the present disclosure may search for the feature quantities at higher speed.

In the information processing system according to another aspect, the optimization may include: calculating the physical property value of the composition as an estimated physical property value by inputting the feature vector to the regression model for each of a plurality of the feature vectors; and acquiring at least one of a plurality of the estimated physical property values as a solution. Since the solution is acquired from the plurality of estimated physical property values obtained from the plurality of feature vectors, the accuracy of the optimization may be improved.

In the information processing system according to another aspect, the at least one processor may be configured to: acquire a reference physical property value serving as a reference in the optimization; and acquire the at least one estimated physical property value corresponding to the reference physical property value, among the plurality of estimated physical property values, as the solution. By using the reference physical property value and the corresponding estimated physical property value as the solution for the optimization, it is possible to more accurately search for the feature quantities of candidate components for forming the desired composition.

In the information processing system according to another aspect, the at least one processor may be configured to: terminate the repetition of the optimization based on the number of types of the candidate components remaining after the exclusion processing. By setting the termination condition of the repetition based on the number of types of remaining candidate components, it is possible to search for the feature quantities of candidate components in consideration of the preparation of candidate components for obtaining the desired composition, the production process of the composition, and the like.

In the information processing system according to another aspect, the at least one processor may be configured to exclude a candidate component having the feature quantity equal to or less than a threshold value in the excluding. By using the threshold value, it is possible to efficiently exclude the candidate component.

In the information processing system according to another aspect, the at least one processor may be configured to exclude a candidate component having the minimum feature quantity in the excluding. By excluding the candidate component with the minimum feature quantity, it is possible to reliably perform the exclusion processing.

In the information processing system according to another aspect, the feature quantity may indicate a blending amount of the candidate component for forming the composition. By setting the feature quantity in this manner, it is possible to search for the blending amount of each candidate component that should be prepared to form the desired composition.

### Modification Examples

The above description has been made in detail based on the embodiment of the present disclosure. However, the present disclosure is not limited to the embodiment described above. The present disclosure can be modified in various ways without departing from its gist.

For example, the information processing method executed by at least one processor is not limited to the above example. For example, some of the steps or processes described above may be omitted, or the steps may be executed in a different order. In addition, any two or more steps among the above-described steps may be combined, or some of the steps may be modified or deleted. Alternatively, other steps may be executed in addition to each of the above steps.

In a case of comparing the magnitudes of two numerical values in the information processing system 10, either of the two criteria of “equal to or greater than” and “greater than” may be used, or either of the two criteria of “equal to or less than” and “less than” may be used. Such criteria selection does not change the technical significance of the process of comparing the magnitudes of two numerical values.

In the present disclosure, the expression “at least one processor performs a first process, performs a second process, . . . , and performs an n-th process” or the expression corresponding thereto shows a concept including a case where a processor that performs n processes from the first process to the n-th process changes on the way. That is, this expression shows a concept including both a case where all of the n processes are performed by the same processor and a case where the processor is changed according to any policy in the n processes.

### REFERENCE SIGNS LIST

10: information processing system, 11: acquisition unit, 12: optimization unit, 13: exclusion unit, 14: determination unit, 15: output unit, 21: candidate component database.

1. An information processing system comprising at least one processor,
wherein the at least one processor is configured to:
repeat optimization using a regression model, which calculates a physical property value of a composition from a feature vector indicating feature quantities of a candidate component group based on a plurality of candidate components, while performing exclusion processing for excluding at least one candidate component from the candidate component group; and
identify feature quantities of one or more candidate components remaining after the repetition, and
wherein the exclusion processing includes:
selecting the feature vector corresponding to a solution for the physical property value obtained by the optimization; and
excluding the at least one candidate component from the candidate component group based on the selected feature vector.

2. The information processing system according to claim 1, wherein the optimization includes:
calculating the physical property value of the composition as an estimated physical property value by inputting the feature vector to the regression model, for each of a plurality of the feature vectors; and
acquiring at least one of a plurality of the estimated physical property values as the solution.

3. The information processing system according to claim 2, wherein the at least one processor is configured to:
acquire a reference physical property value serving as a reference in the optimization; and
acquire the at least one estimated physical property value corresponding to the reference physical property value, among the plurality of estimated physical property values, as the solution.

4. The information processing system according to claim 1, wherein the at least one processor is configured to terminate the repetition of the optimization based on the number of types of the candidate components remaining after the exclusion processing.

5. The information processing system according to claim 1, wherein the at least one processor is configured to exclude a candidate component having the feature quantity equal to or less than a threshold value, in the excluding.

6. The information processing system according to claim 1, wherein the at least one processor is configured to exclude a candidate component having the minimum feature quantity, in the excluding.

7. The information processing system according to claim 1, wherein the feature quantity indicates a blending amount of the candidate component for forming the composition.

8. An information processing method executed by an information processing system including at least one processor, the method comprising:
repeating optimization using a regression model, which calculates a physical property value of a composition from a feature vector indicating feature quantities of a candidate component group based on a plurality of candidate components, while performing exclusion processing for excluding at least one candidate component from the candidate component group; and
identifying feature quantities of one or more candidate components remaining after the repeating,
wherein the exclusion processing includes:
selecting the feature vector corresponding to a solution for the physical property value obtained by the optimization; and
excluding the at least one candidate component from the candidate component group based on the selected feature vector.

9. A non-transitory computer-readable storage medium storing an information processing program causing a computer to execute:
repeating optimization using a regression model, which calculates a physical property value of a composition from a feature vector indicating feature quantities of a candidate component group based on a plurality of candidate components, while performing exclusion processing for excluding at least one candidate component from the candidate component group; and
identifying feature quantities of one or more candidate components remaining after the repeating,
wherein the exclusion processing includes:
selecting the feature vector corresponding to a solution for the physical property value obtained by the optimization; and
excluding the at least one candidate component from the candidate component group based on the selected feature vector.
